(19) United States
(12) Patent Application Publication
(10) Pub. No.: US 2012/0039144 A1
(43) Pub. Date: Feb. 16, 2012

(54) Semiconductor device with shortened data read time

(75) Inventors: Hidenori Tobori, Tokyo (JP); Hisayuki Nagamine, Tokyo (JP)

(73) Assignee: ELPIDA MEMORY, INC., Tokyo (JP)

(21) Appl. No.: 13/137,388

(22) Filed: Aug. 10, 2011

(30) Foreign Application Priority Data
Aug. 13, 2010 (JP) 2010-181299

(51) Int. Cl. G11C 7/06

(52) U.S. Cl. 365/207

(57) ABSTRACT

A semiconductor device includes: a plurality of memory cell arrays arranged along a predetermined direction; a plurality of bit lines to read data stored in a plurality of memory elements; a plurality of sense amplifier sections that amplify potentials appearing on selected bit lines, that amplify potentials in opposite phase to the potentials, and that output data signals and inverted data signals; a data output circuit that outputs the data to an external circuit based on the data signals and the inverted data signals; and a plurality of local signal lines extending parallel to the predetermined direction, to transmit the data signal and the inverted data signals to the data output circuit, wherein the local signal lines include two adjacent signal lines which are positionally switched around in a direction perpendicular to the predetermined direction alternately at predetermined intervals.

This application is based upon and claims the benefit of priority from Japanese Patent Application No. 2010-181299 filed on Aug. 13, 2010, the content of which is incorporated by reference.

### BACKGROUND OF THE INVENTION

1. Field of the Invention

The present invention relates to a semiconductor device having a plurality of memory elements.

2. Description of Related Art

The configuration of a DRAM (Dynamic Random Access Memory) as an example of a semiconductor device will be described below. FIG. 1 of the accompanying drawings is a block diagram showing a configurational example of a semiconductor device according to the related art.

As shown in FIG. 1, semiconductor device 10 has a plurality of memory cell blocks 20-1 through 20-n (n represents an integer of 1 or greater) each including a plurality of memory elements, CA pad 31 for inputting address signals and command signals, DQ pad 32 for sending data to and receiving data from an external circuit, column decoders 41 and row decoders 42 for specifying memory elements according to address signals, data input/output control circuit 51 for controlling the inputting and outputting of data, and data output circuit 52 and data input circuit 53 which are connected between data input/output control circuit 51 and DQ pad 32.

Data output circuit 52 has a data amplifier (not shown) and an output circuit (not shown). Each of memory cell blocks 20-1 through 20-n is combined with column decoder 41 and row decoder 42. A memory cell block that is combined with column decoder 41 and row decoder 42 will be referred to as “bank”.

FIG. 2 of the accompanying drawings is a block diagram showing a configurational example of each memory cell block of the semiconductor device shown in FIG. 1. In FIG. 2, a vertical-axis direction is referred to as a Y-axis direction and a horizontal-axis direction as an X-axis direction.

As shown in FIG. 2, the memory cell block has a matrix of memory cell arrays 22 each including a plurality of memory elements. Each of the memory cell arrays will be referred to as “MAT”. Since the memory cell block includes a plurality of MATs 22, each MAT serves as one of a plurality of units into which the memory elements in the memory cell block are divided.

Word lines 21 are connected to row decoder 42. Each of word lines 21 extends through a linear array of MATs 22 that are disposed along the X-axis direction. Though only one word line 21 is shown in FIG. 2, there are as many word lines 21 as the number of memory elements disposed along the Y-axis direction in each of MATs 22. Word lines 21 are connected to the gate electrodes of respective select transistors of the memory elements in each MAT 22.

Sense amplifier sections (hereinafter referred to as “SAMPs”) 23 are disposed on the respective opposite sides of each MAT 22 which are spaced along the Y-axis direction. Subword drivers (hereinafter referred to as “SWDs”) 24 are disposed on the respective opposite sides of each MAT 22 which are spaced along the X-axis direction.

Local input/output lines (hereinafter referred to as “LIO lines”) serving as signal lines for guiding the potentials of the bit lines of the select transistors of the memory elements to data output circuit 52 are connected to SAMPs 23. The LIO lines extend parallel to the X-axis direction. The LIO lines are connected to main input/output lines (hereinafter referred to as “MIO lines”) which extend parallel to the Y-axis direction. Y switch lines (hereinafter referred to as “YS lines”) for transmitting signals to connect the bit lines of the select transistors of the memory elements to the LIO lines and the sense amplifiers (not shown) are connected to SAMPs 23. The YS lines are connected to column decoders 41.

Regions where lines connected to SWDs 24 and the LIO lines cross each other three-dimensionally while being electrically isolated from each other are called subword crosses (hereinafter referred to as “SWCs”) 25. Examples of semiconductor devices which have configurations similar to is the layout shown in FIG. 2 are disclosed in JP2006-172577A and JP2006-253270A.

FIG. 3 of the accompanying drawings is a block diagram showing a configurational example of a sense amplifier section according to the related art. SAMPs 23a, 23b shown in FIG. 3 refer to sense amplifier sections that are compatible with an open bit line structure which is employed in a DRAM having a cell area 6F².

As shown in FIG. 3, YS lines YS0 through YSn are disposed between the SAMPs. SAMP 23a is disposed between MAT22a and MAT22b. SAMP 23a includes a plurality of sense amplifiers 26, a plurality of bit lines equalizers 27, and a pair of Y switch sections 28a, 28b disposed in sandwiching relation to sense amplifiers 26 and bit lines equalizers 27.

Four bit lines BLL0T through BLL3T that are connected respectively to the select transistors in MAT 22a and four bit lines BLR0B through BLR3B that are connected respectively to the select transistors in MAT 22b are connected to sense amplifiers 26 and bit lines equalizers 27.

The memory elements in MAT 22a which are connected to bit lines BLL0T through BLL3T store data entered from an external circuit, and the memory elements in MAT 22b which are connected to bit lines BLR0B through BLR3B store data in opposite phase entered from the external circuit. The memory elements in MAT 22a which are connected to bit lines BLL0T through BLL3T are called true cells.

If the memory cell connected to bit line BLL0T stores a high signal, then the memory cell connected to bit line BLR0B stores a low signal. The memory elements connected to bit lines BLL0T through BLL3T will hereinafter be referred to as true memory elements, and the memory elements connected to bit lines BLR0B through BLR3B as bar memory elements.

Sense amplifier 26 amplifies a potential that appears on bit line BLLkT (k represents an integer equal or greater than 0) that is selected by an address signal. A signal which represents the amplified potential will hereinafter be referred to as “data signal” because the amplified potential corresponds to data recorded in a memory element. Sense amplifier 26 also amplifies a potential that appears on bit line BLRkB which is in opposite phase to the potential that appears on bit line BLLkT. A signal which represents the amplified potential will hereinafter be referred to as “inverted data signal”.

Y switch section 28a includes a plurality of MOS (Metal Oxide Semiconductor) transistors 211a through 211d. MOS transistors 211a through 211d have respective gate electrodes connected to YS line YS0, respective drain electrodes connected respectively to bit lines BLL0T through BLL3T connected to MAT 22a, and respective source electrodes connected respectively to LIO lines LIO0T through LIO3T.

Y switch section 28b includes a plurality of MOS transistors 212a through 212d. MOS transistors 212a through 212d have respective gate electrodes connected to YS line YS0, respective drain electrodes connected respectively to bit lines BLR0B through BLR3B which are connected to MAT 22b, and respective source electrodes connected respectively to LIO lines LIO0B through LIO3B.

The letter “T” in LIO0T through LIO3T means that LIO lines LIO0T through LIO3T are signal lines connected to true memory elements, and the numerals “0” through “3” therein represent numbers for identifying the four bit lines in MAT 22a. The letter “B” in LIO0B through LIO3B means that LIO lines LIO0B through LIO3B are signal lines connected to bar memory elements, and the numerals “0” through “3” therein represent numbers for identifying the four bit lines in MAT 22b.

LIO lines LIO0T through LIO3T and LIO lines LIO0B through LIO3B are connected to LIO selector 220 which is connected to DQ pad 32 through data output circuit 52. Depending on a selected address, LIO selector 220 selects two of LIO lines LIO0T through LIO3T and LIO lines LIO0B through LIO3B as a pair and connects the selected LIO lines to data output circuit 52.

FIG. 4 of the accompanying drawings is a schematic diagram showing an example of the layout of the Y switch sections shown in FIG. 3.

Since Y switch sections 28a, 28b are identical in configuration to each other, only Y switch section 28a will be described below. FIG. 4 also shows SAMP 23a and Y switch section 281 in SAMP 23b which is spaced from SAMP 23a in the X-axis direction with an SWC interposed therebetween.

Y switch section 281 includes MOS transistors 221a through 221d which correspond to MOS transistors 211a through 211d of Y switch section 28a. MOS transistors 221a through 221d are connected respectively to bit lines BL4 through BL7.

The active pattern of each MOS transistor is represented by a dotted rectangle, and the pattern of each contact plug that connects interconnection in an upper layer and interconnection in lower layer to each other is represented by a hatched circular dot. YS line YS0 corresponds to the gate electrodes of MOS transistors 211a through 211d, and controls MOS transistors 211a through 211d to be turned on and off. YS line YS1 corresponds to the gate electrodes of MOS transistors 221a through 221d, and controls MOS transistors 221a through 221d to be turned on and off.

LIO line LIO0T is connected to MOS transistors 211a, 221a, and LIO line LIO2T is connected to MOS transistors 211c, 221c. LIO line LIO1T is connected to MOS transistors 211b, 221b, and LIO line LIO3T is connected to MOS transistors 211d, 221d. SAMPs are thus disposed one on each side of an SWC in the X-axis direction, and their Y switch sections are connected to each other by LIO lines.

A process of reading memory cells of the DRAM which is constructed as described above will be briefly described below.

When an address signal and a command signal are entered from an external circuit via CA pad 31, the potential on word line 21 selected by row decoder 42 increases, and the potential which corresponds to the data stored in a memory element connected to word line 21 appears on bit line BLLkT, and the potential in opposite phase appears on bit line BLRkB. The potential that appears on bit line BLLkT and the potential that appears on bit line BLRkB are amplified by sense amplifier 26.

Signals which represent the potentials amplified by sense amplifier 26, i.e., a data signal and an inverted data signal, are transmitted respectively to paired LIO lines LIOjT, LILjB (j represents an integer of 1 or greater) when the MOS transistors of the Y switch sections that are selected by column decoder 41 via a YS line, turn on. The data signal and the inverted data signal that are transferred along LIO lines LIOjT, LILjB are sent to data output circuit 52 via a pair of MIO lines. Data output circuit 52 outputs data represented by the data signal and the inverted data signal to an external circuit via DQ pad 32.

Coupling noise of four LIO lines in each of the Y switch sections of the sense amplifier sections that are connected to the true and bar cells will be described below. Of the four LIO lines in each of Y switch sections connected to the true and bar cells, each of two inner LIO lines LIO2, LIO1 (see FIG. 5 of the accompanying drawings) is spaced given distances from other LIO lines on the opposite sides thereof. Therefore, two inner LIO lines LIO2, LIO1 are subject to coupling noise that is twice as large as the coupling noise that is applied to outer two LIO lines LIO0, LIO3.

FIG. 6 of the accompanying drawings is a table that shows the operational states of the LIO lines of the switch sections shown in FIG. 4 and that shows how coupling noise affects the operational states of the LIO lines. The table is shared by the LIO lines that are in the Y switch sections connected to the true and bar cells, so that letters indicating which of true cells and bar cells the LIO lines belong to are omitted from FIG. 6.

As shown in FIG. 6, there are sixteen patterns depending on the operational states (hereinafter simply referred to as “states”) of the LIO lines. Each of the states shown in FIG. 6 includes signals of Y switch section 281 on the left side of the SWC and signals of Y switch section 28a on the right side of the SWC for respective LIO lines L100 through LIO3. The signals include high signals represented by “H” and low signals represented by “L”.

In states 5, 6, 11, 12, LIO line L102 is positioned between LIO lines to which there is applied a potential that is in opposite phase to a potential applied to LIO line L102. In states 3, 6, 11, 14, LIO line LIO1 is positioned between LIO lines to which there is applied a potential that is in opposite phase to a potential applied to LIO line LIO1. It can be seen from FIG. 6 that there are six states 3, 5, 6, 11, 12, 14 in which the coupling noise posed on LIO line LIO1 or LIO line L102 or both is maximum. In these six states, LIO line LIO1 and LIO line L102 tend to cause a delay in transition due to the effect of coupling noise, resulting in a longer data read time.

### SUMMARY

In one embodiment, there is provided a semiconductor device that includes a plurality of memory cell arrays arranged along a predetermined direction, each of the memory cell arrays including a memory elements, a plurality of bit lines associated with the memory cell arrays to read data stored in the memory elements, a plurality of sense amplifier sections associated with the memory cell arrays that amplify potentials which correspond to the data, appearing on selected ones of the bit lines, that amplify potentials in opposite phase to the potentials, that output data signals representing the amplified potentials corresponding to the data in a direction which is different from the predetermined direction, and that output inverted data signals which are in opposite phase to the data signals in a direction which is opposite to the direction in which the data signals are output, a data output circuit that outputs the data to an external circuit based on the data signals and the inverted data signals, and a plurality of local signal lines extending parallel to the predetermined direction to transmit the data signal and the inverted data signals to the data output circuit, wherein the local signal lines include two adjacent signal lines which are positionally switched around in a direction perpendicular to the predetermined direction alternately at predetermined intervals.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing a configurational example of a semiconductor device according to the related art;

FIG. 2 is a block diagram showing a configurational example of each memory cell block of the semiconductor device shown in FIG. 1;

FIG. 3 is a block diagram showing a configurational example of a sense amplifier section according to the related art;

FIG. 4 is a schematic diagram showing an example of the layout of the Y switch sections shown in FIG. 3;

FIG. 5 is a diagram illustrative of the effect of coupling noise between LIO lines of the switch sections shown in FIG. 4;

FIG. 6 is a table showing the operational states of the LIO lines of the switch sections shown in FIG. 4 and how coupling noise affects the operational states of the LIO lines;

FIG. 7 is a schematic diagram showing a configurational example of an essential portion of a semiconductor device according to a first exemplary embodiment of the present invention;

FIG. 8 is a block diagram showing a configurational example of a memory cell block of the semiconductor device according to the first exemplary embodiment;

FIG. 9 is a table showing the operational states of LIO lines and how coupling noise affects the operational states of the LIO lines in the semiconductor device according to the first exemplary embodiment;

FIG. 10 is a diagram illustrative of the manner in which the effect of coupling noise between inner LIO lines is reduced;

FIG. 11 is a block diagram showing another configurational example of the memory cell block of the semiconductor device according to the first exemplary embodiment; and

FIG. 12 is a schematic diagram showing a configurational example of an essential portion of a semiconductor device according to a second exemplary embodiment of the present invention.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

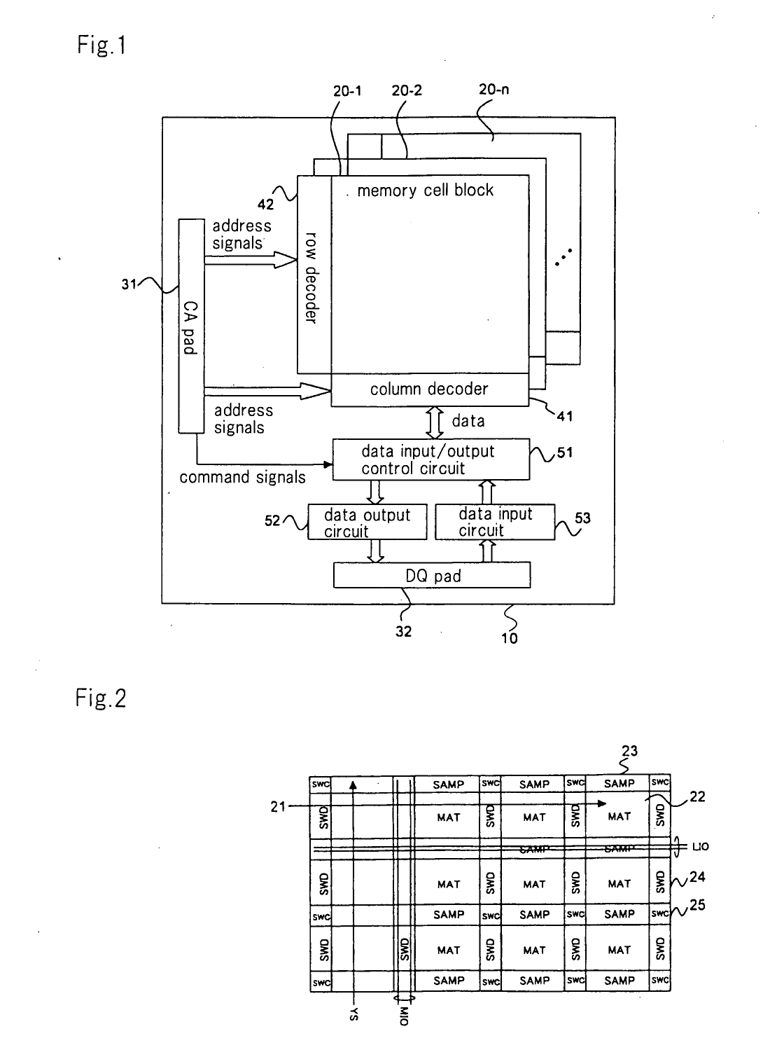

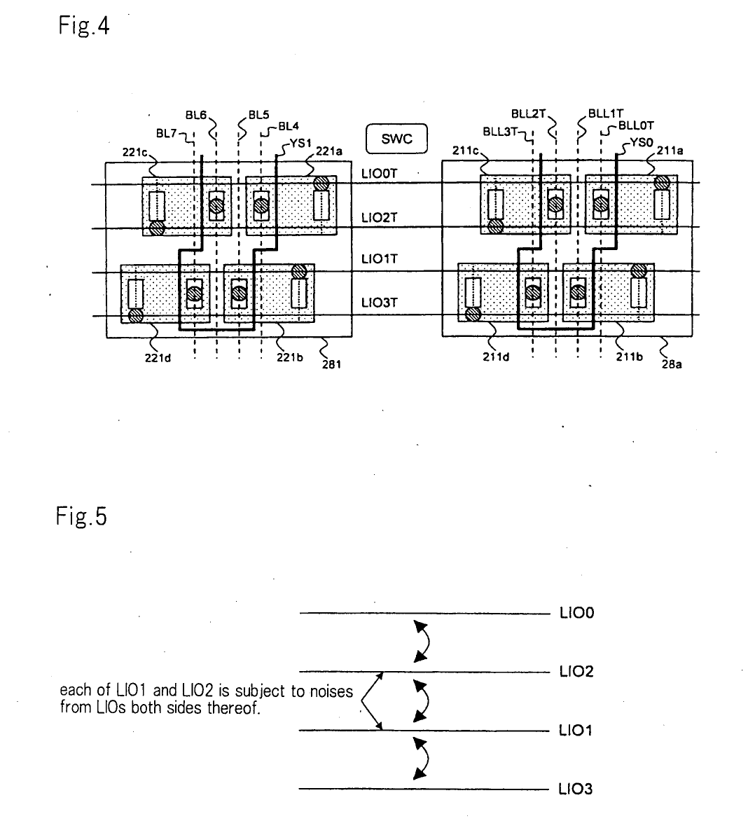

Semiconductor devices according to exemplary embodiments of the present invention are different from the semiconductor device according to the related art shown in FIG. 1 with respect to a portion of a memory cell block. Therefore, structural details other than the memory cell block will be omitted from illustration, and only details of the semiconductor devices according to the exemplary embodiments which are different from the semiconductor device shown in FIGS. 1 through 4 will be described below.

### First Exemplary Embodiment

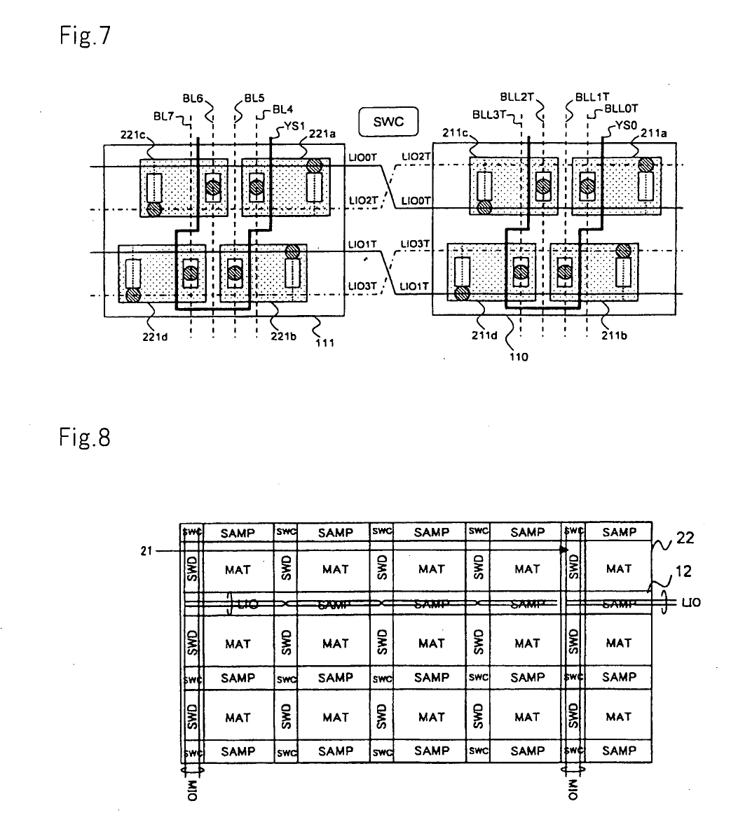

A semiconductor device according to a first exemplary embodiment of the present invention will be described below. FIG. 7 is a schematic diagram showing a configurational example of an essential portion of the semiconductor device according to the first exemplary embodiment of the present invention. In FIG. 7, a horizontal-axis direction as an X-axis direction, and a vertical-axis direction is referred to as a Y-axis direction.

In the present exemplary embodiment, the configuration of Y switch sections connected to true memory elements and the layout of LIO lines with respect thereto according to features of the present invention will be described above. The configuration of Y switch sections connected to bar memory elements and the layout of LIO lines with respect thereto according to features of the present invention are similar and will not be described in detail below.

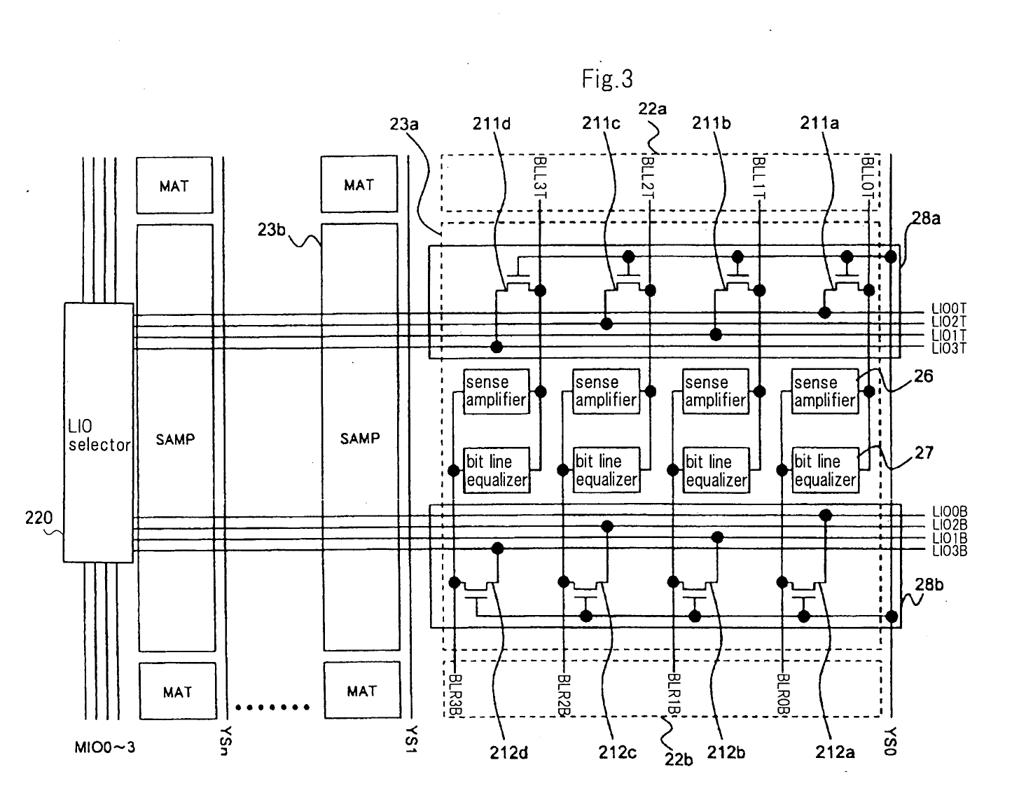

According to the present exemplary embodiment, Y switch section 110 shown in FIG. 7 is included instead of Y switch section 28a in the sense amplifier section shown in FIG. 3, and Y switch section 111 shown in FIG. 7 is included instead of Y switch section 281 in the sense amplifier section shown in FIG. 3. According to the present exemplary embodiment, furthermore, in the SWC between switch section 110 and switch section 111, the first and second ones, i.e., LIO lines LIO0T, LIO2T, of the four LIO lines LIO0T through LIO3T cross each other (are twisted) in electrically insulated relation to each other, and the third and fourth ones, i.e., LIO lines LIO1T, LIO3T, of the four LIO lines LIO0T through LIO3T cross each other (are twisted) in electrically insulated relation to each other.

In FIG. 7, LIO lines LIO2T, LIO3T are indicated by the dot-and-dash lines in order to make the crossing LIO lines more identifiable.

In Y switch section 111, LIO lines LIO0T, LIO2T extend parallel to the X-axis direction, with LIO line LIO0T being disposed above LIO line LIO2T. In the SWC between Y switch sections 110, 111, LIO lines LIO0T, LIO2T are positionally switched around in the Y-axis direction. In Y switch section 110, LIO lines LIO0T, LIO2T extend parallel to the X-axis direction, with LIO line LIO2T being disposed above LIO line LIO0T. LIO lines LIO0T, LIO2T are positionally switched around in the Y-axis direction alternately in the successive Y switch sections.

In Y switch section 111, LIO lines LIO1T, LIO3T extend parallel to the X-axis direction, with LIO line LIO1T being disposed above LIO line LIO3T. In the SWC between Y switch sections 110, 111, LIO lines LIO1T, LIO3T are positionally switched around in the Y-axis direction. In Y switch section 110, LIO lines LIO1T, LIO3T extend parallel to the X-axis direction, with LIO line LIO3T being disposed above LIO line LIO1T. LIO lines LIO1T, LIO3T are positionally switched around in the Y-axis direction alternately in the successive Y switch sections.

According to the present exemplary embodiment, the first and second LIO lines, i.e., LIO lines LIO0T, LIO2T, are twisted in electrically insulated relation to each other, and the third and fourth LIO lines, i.e., LIO lines LIO1T, LIO3T, are twisted in electrically insulated relation to each other, is in the SWC. This arrangement is effective for reducing the effect of coupling noise between adjacent LIO lines for reasons to be described later.

One example of a pattern in which two LIO lines are twisted in electrically insulated relation to each other will be described below. It is assumed that LIO lines LIO0T, LIO2T are twisted in electrically insulated relation.

LIO lines LIO0T, LIO2T are formed of a first aluminum layer. In the twisted region in the SWC, LIO line LIO0T is formed of a second aluminum layer which is disposed above the first aluminum layer. LIO line LIO0T formed of the second aluminum layer is called “second aluminum layer LIO0T”. LIO line LIO0T which extends from Y switch section 111 is connected to one end of second aluminum layer LIO0T through a via plug, and the other end of second aluminum layer LIO0T is connected to LIO line LIO0T which extends from Y switch section 110 through a via plug.

The above structure makes it possible to twist LIO lines LIO0T, LIO2T in electrically insulated relation to each other. In the twisted region in the SWC, LIO line LIO2T may be formed of the second aluminum layer. LIO lines LIO1T, LIO3T may be twisted in the same pattern as LIO lines LIO0T, LIO2T.

FIG. 8 is a block diagram showing a configurational example of a memory cell block of the semiconductor device according to the first exemplary embodiment. As shown in FIG. 8, the memory cell block includes Y switch sections 110, 110 and LIO lines LIO0T through LIO3T shown in FIG. 7.

The lengths of LIO lines are determined depending on the MAT configuration according to the specifications of the semiconductor device. Therefore, a single LIO line may extend over a plurality of SWCs. As shown in FIG. 8, two LIO lines may be twisted in each of the SWCs to change the coupling between two interconnections of one layer at small intervals.

The reasons why the arrangement of the present exemplary embodiment is effective for reducing the effect of coupling noise between LIO lines will be described below.

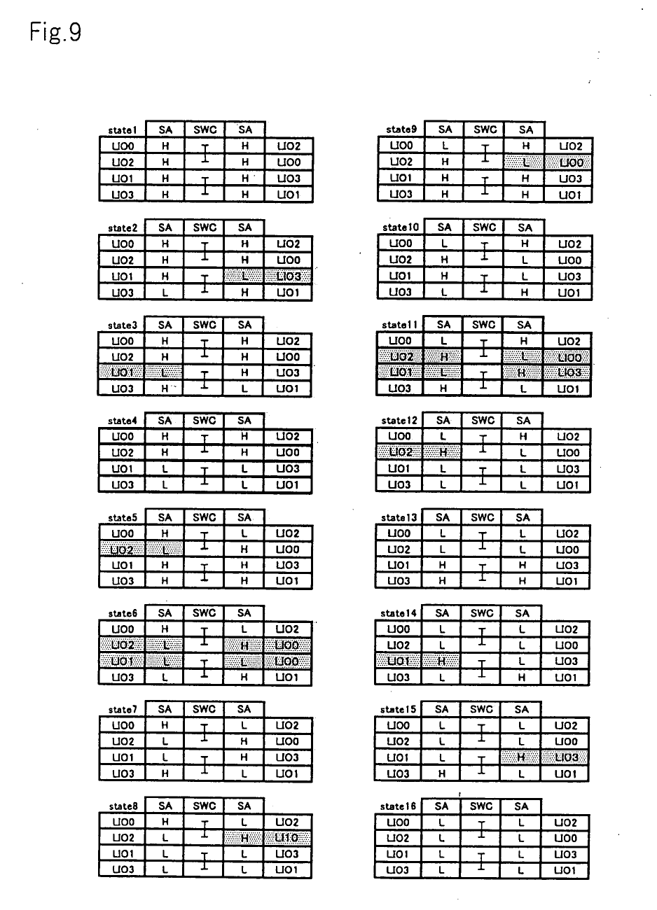

FIG. 9 is a table showing the operational states of LIO lines and how coupling noise affects the operational states of the LIO lines in the semiconductor device according to the first exemplary embodiment. The table is shared by the LIO lines that are in the Y switch sections connected to the true and bar cells, so that letters indicating which of true cells and bar cells the LIO lines belong to are omitted from FIG. 9.

As shown in FIG. 9, there are sixteen patterns depending on the states of the LIO lines. Each of the states shown in FIG. 9 includes signals of Y switch section 111 on the left side of the SWC and signals of Y switch section 110 on the right side of the SWC for respective LIO lines L100 through LIO3.

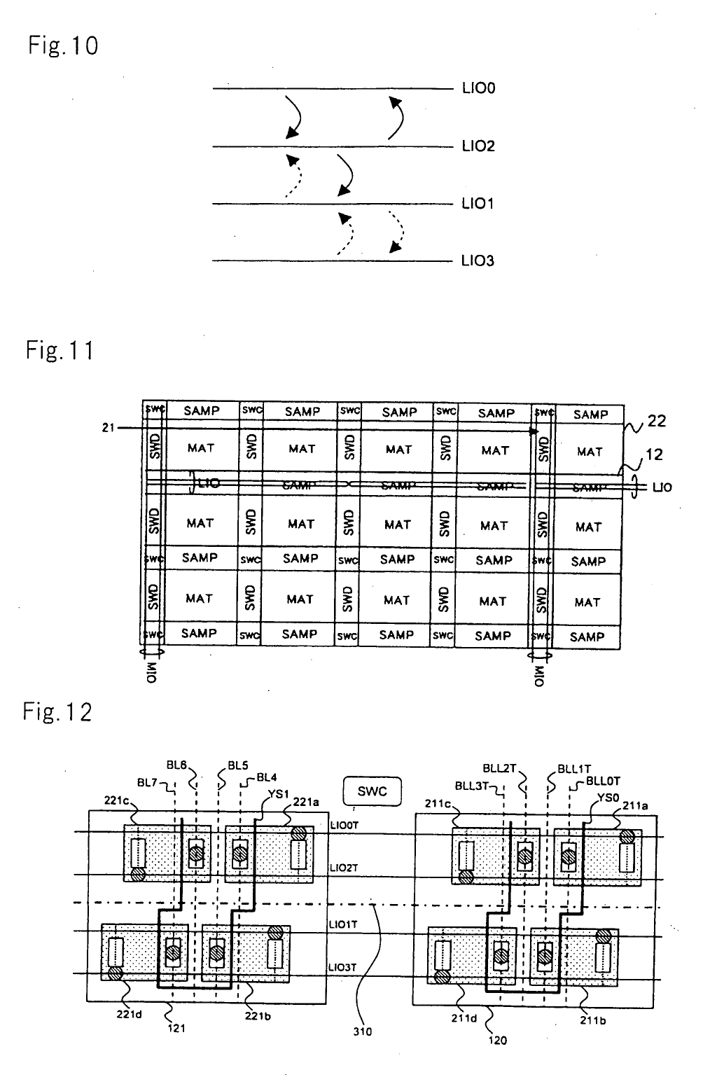

The reasons why noise from adjacent LIO lines is reduced depending on the potentials on the LIO lines will be described below. FIG. 10 is a diagram illustrative of the effect of coupling noise between inner LIO lines in Y switch section 111 in state 4 in the table shown in FIG. 9. In FIG. 10, solid-line arrows represent noise due to a high signal, and broken-line arrows represent noise due to a low signal.

In state 4, a high potential is applied to LIO lines LIO0, LIO2, and a low potential is applied to LIO lines LIO1, LIO3. Since the high potential applied to LIO line LIO0 is in opposite phase to the low potential applied to LIO line LIO1, noise imposed on LIO line LIO2 by the high potential applied to LIO line LIO0 and noise imposed on LIO line LIO2 by the low potential applied to LIO line LIO1 cancel each other out. Similarly, since the high potential applied to LIO line LIO2 is in opposite phase to the low potential applied to LIO line LIO3, noise imposed on LIO line LIO1 by the high potential applied to LIO line LIO2 and noise imposed on LIO line LIO1 by the low potential applied to LIO line LIO3 cancel each other out. As a result, each of outer two LIO lines LIO0, LIO3 is subject to noise from either one of two inner LIO lines LIO1, LIO2.

In state 4 shown in FIG. 10, therefore, coupling noise is prevented from being applied to each of two inner LIO lines LIO1, LIO2.

In six states 1, 4, 7, 10, 13, 16, the potentials applied to the LIO lines on the opposite sides of the two inner LIO lines are in opposite phase to each other or the potential applied to each of the two inner LIO lines is in phase with the potentials applied to the LIO lines on the opposite sides of the two inner LIO lines. Therefore, no coupling noise causes problems on the two inner LIO lines.

In state 2, the signal on LIO line L100 and the signal on LIO line L102 are high, and hence the signals on LIO lines L1O0, L1O2 that are twisted are in phase with each other. The signal on LIO line LIO1 is high and the signal on LIO line LIO3 is low, and hence the signals on LIO lines LIO1, LIO3 that are twisted are in opposite phase to each other.

In Y switch section 111 in state 2, no coupling noise causes problems on two inner LIO lines L102, LIO1. In Y switch section 110 in state 2, LIO line LIO3 is subject to coupling noise because the signal on LIO line LIO3 is low and the signals on LIO lines LIO0, LIO1 on the opposite sides of LIO line LIO3 are high. However, since LIO lines LIO1, LIO3 are twisted, LIO line LIO3 is not subject to coupling noise in Y switch section 111 though it is subject to coupling noise in Y switch section 110. Therefore, the effect of coupling noise on LIO line LIO3 is reduced by one half as a whole.

States 8, 9, 15 are similar to state 2. In states 8, 9, 15, the effect of coupling noise on an inner LIO line is reduced by one half as a whole.

In state 3, the signal on LIO line L100 and the signal on LIO line LIO2 are high, and hence the signals on LIO lines LIO0, LIO2 that are twisted are in phase with each other. The signal on LIO line LIO1 is low and the signal on LIO line LIO3 is high, and hence the signals on LIO lines LIO1, LIO3 that are twisted are in opposite phase to each other.

In Y switch section 110 in state 3, no coupling noise causes problems on two inner LIO lines LIO0, LIO3. In Y switch section 111 in state 3, LIO line LIO1 is subject to coupling noise because the signal on LIO line LIO1 is low and the signals on LIO lines L102, LIO3 on the opposite sides of LIO line LIO1 are high. However, since LIO lines LIO1, LIO3 are twisted, LIO line LIO1 is not subject to coupling noise in Y switch section 110 though it is subject to coupling noise in Y switch section 111. Therefore, the effect of coupling noise on LIO line LIO1 is reduced by one half as a whole.

States 5, 12, 14 are similar to state 3. In states 5, 12, 14, the effect of coupling noise on an inner LIO line is reduced by one half as a whole.

Consequently, it can be seen from FIG. 9 that the effect of coupling noise imposed on the two inner LIO lines from LIO lines adjacent thereto are reduced by one half.

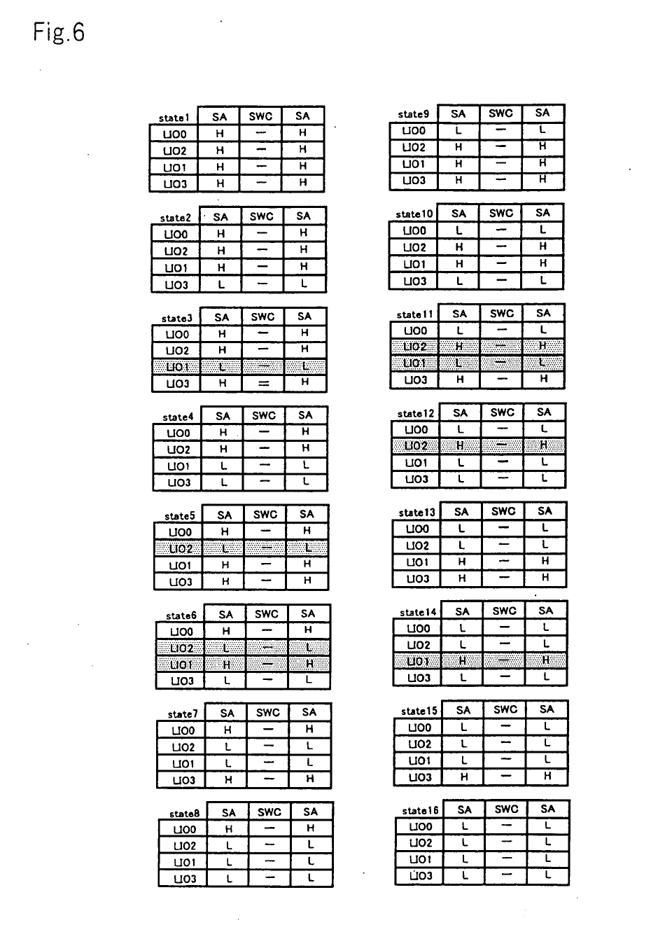

In the table shown in FIG. 9, the coupling noise on the two inner LIO lines is maximum in state 6 and state 11. Comparison between the table shown in FIG. 6 and the table shown in FIG. 9 indicates that the effect of coupling noise is reduced according to the first exemplary embodiment.

According to the first exemplary embodiment, since two adjacent LIO lines are twisted in electrically insulated relation to each other in an SWC, an inner LIO line is positioned between LIO lines that are kept at potentials which are in opposite phase to a potential that is applied to the inner LIO line and is subject to noise from the LIO lines on the opposite sides thereof in SAMPs on both sides of the SWC, but is subject to noise from only one of the LIO lines on the opposite sides in the other SAMP.

Stated otherwise, since two adjacent local signal lines are positionally switched around alternately at predetermined intervals, even if one of the local signal lines is subject to coupling noise from other local signal lines in a zone, it is subject to reduced coupling noise in another zone. Therefore, when data are read from memory elements, the data are subject to reduced coupling noise between the LIO lines, and hence the data read time required to read the data is prevented from increasing.

If four LIO lines are grouped into two pairs of LIO lines including two adjacent LIO lines that are twisted, and signals that are transmitted through one of the pairs of LIO lines are in opposite phase to each other and signals that are transmitted through the other pair of LIO lines are in phase with each other, then coupling noise generated between the pair of LIO lines whose signals are in opposite phase to each other is reduced by one half.

As shown in FIG. 11, a single LIO line may be twisted once as closely to its central portion as possible. In view of the total amount of coupling noise and increase in the contact resistance of the twisted portion of the LIO line, it is not necessary to twist two LIO lines at each SWC. A single LIO line that is twisted once as closely to its central portion as possible is effective for reducing coupling noise between adjacent LIO lines.

### Second Exemplary Embodiment

A semiconductor device according to a second exemplary embodiment of the present invention incorporates a shield line for protection against noise between LIO lines.

The semiconductor device according to the second exemplary embodiment will be described below. FIG. 12 is a schematic diagram showing a configurational example of the layout of Y switch sections of a sense amplifier section of the semiconductor device according to the second exemplary embodiment. In the second exemplary embodiment, the configuration of Y switch sections connected to true memory elements and the layout of LIO lines with respect thereto will be described above. The configuration of Y switch sections connected to bar memory elements and the layout of LIO lines with respect thereto are similar and will not be described in detail below.

According to the present exemplary embodiment, Y switch is section 120 shown in FIG. 12 is included instead of Y switch section 28a in the sense amplifier section shown in FIG. 3, and Y switch section 121 shown in FIG. 12 is included instead of Y switch section 281 in the sense amplifier section shown in FIG. 3. According to the present exemplary embodiment, furthermore, four LIO lines extending through Y switch section 120 and Y switch section 121 are grouped into a pair of two upper LIO lines LIO0T, LIO2T and a pair of two lower LIO lines LIO1T, LIO3T, and shield line 310 is disposed between these pairs of LIO lines. Shield line 310 is formed of the same layer as the four LIO lines, and is connected to a power supply potential or a ground potential.

LIO line LIO2T is protected against noise due to a potential on LIO line LIO1T by shield line 310, and hence is subject to only noise from LIO line LIO0T. LIO line LIO1T is protected against noise due to a potential on LIO line LIO2T by shield line 310, and hence is subject to only noise from LIO line LIO3T.

According to the present exemplary embodiment, inasmuch as each of the two inner LIO lines is subject to only noise from an LIO line on one side thereof, the effect of noise on the LIO lines is reduced. Since the shield line is formed of the same layer as the four LIO lines, the semiconductor device can be fabricated without the need of additional fabrication steps.

According to the present exemplary embodiment, the effect of coupling noise between LIO lines is reduced. As a result, a delay in transition due to the effect of coupling noise is reduced, preventing the data read time from increasing.

Semiconductor memory devices having a plurality of memory is cell blocks have been described in the above exemplary embodiments. However, the present invention is also applicable to system LSI (Large Scale Integration) circuits including logic circuits as well as memory devices.

It is apparent that the present invention is not limited to the above embodiments, but may be modified and changed without departing from the scope and spirit of the invention.

What is claimed is:

1. A semiconductor device comprising:
a plurality of memory cell arrays arranged along a predetermined direction, each of said memory cell arrays including a memory elements;
a plurality of bit lines associated with said memory cell arrays, to read data stored in said memory elements;
a plurality of sense amplifier sections associated with said memory cell arrays that amplify potentials which correspond to said data, appearing on selected bit lines, that amplify potentials in opposite phase to said potentials, that output data signals representing the amplified potentials corresponding to said data in a direction which is different from said predetermined direction, and that output inverted data signals which are in opposite phase to said data signals in a direction which is opposite to the is direction in which said data signals are output;
a data output circuit that outputs said data to an external circuit based on said data signals and said inverted data signals; and
a plurality of local signal lines extending parallel to said predetermined direction, to transmit said data signal and said inverted data signals to said data output circuit;
wherein said local signal lines include two adjacent signal lines which are positionally switched around in a direction perpendicular to said predetermined direction alternately at predetermined intervals.

2. The semiconductor device according to claim 1, wherein said predetermined intervals represent the respective lengths of said memory cell arrays in said predetermined direction.

3. The semiconductor device according to claim 1, wherein said predetermined intervals represent one half of the lengths of said local signal lines.

4. A semiconductor device comprising:
a plurality of memory cell arrays arranged along a predetermined direction, each of said memory cell arrays including a memory elements;
a plurality of bit lines associated with said memory cell arrays, to read data stored in said memory elements;
a plurality of sense amplifier sections associated with said memory cell arrays that amplify potentials which correspond to said data, appearing on selected bit lines, that amplify potentials in opposite phase to said potentials, that output data signals representing the amplified potentials corresponding to said data in a direction which is different from said predetermined direction, and that output inverted data signals which are in opposite phase to said data signals in a direction which is opposite to the direction in which said data signals are output;
a data output circuit that outputs said data to an external circuit based on said data signals and said inverted data signals;
a plurality of local signal lines extending parallel to said predetermined direction, to transmit said data signal and said inverted data signals to said data output circuit, said local signal lines including pairs of two adjacent local signal lines; and
a shield line disposed between said pairs of two adjacent local signal lines, said shield line being connected to a power supply potential or a ground potential.
